(19) United States
(12) Patent Application Publication
(10) Pub. No.: US 2026/0164758 A1
(43) Pub. Date: Jun. 11, 2026

(54) 3DIC SHIELDED INDUCTOR

(71) Applicant: Murata Manufacturing Co., Ltd., Kyoto (JP)

(72) Inventors: Ke Li, San Diego, CA (US); Miles Sanner, San Diego, CA (US); Emre Ayranci, San Diego, CA (US)

(21) Appl. No.: 18/972,765

(22) Filed: Dec. 6, 2024

(51) Int. Cl. H10D 80/20; H01L 23/552; H10D 88/00

(52) U.S. Cl. CPC H10D 80/213; H10D 80/215; H10D 88/01; H10W 42/20

(57) ABSTRACT

A three-dimensional integrated circuit includes a first CMOS wafer, a second CMOS wafer disposed on and electrically connected to the first CMOS wafer, one or more thick metal layers including an inductive device disposed on the second CMOS wafer opposite the first CMOS wafer, and a grounded shield positioned to isolate the inductive device from the first CMOS wafer and the second CMOS wafer.

### TECHNICAL FIELD

The present disclosure relates to three-dimensional integrated circuits (3DICs) including a grounded shield to electrically and/or magnetically insulate components within the 3DICs. The present disclosure further relates to devices including such 3DICs and methods of making and using the same.

### BACKGROUND

Three-dimensional integrated circuits (3DICs) include a plurality of stacked wafers or chips each including various electrical components, such as switches, transistors, capacitors, resistors, varactors, diodes, and the like. Although 3DICs enable footprint reduction, some integrated circuits are not amenable to stacking due to signal isolation concerns and potential negative impacts on Q factor.

### BRIEF SUMMARY

According to embodiments of the present disclosure, an integrated circuit includes a wafer including circuitry, an inductor positioned above the wafer, and a grounded shield positioned between the inductor and the circuitry of wafer to electrically and magnetically isolate the inductor from the circuitry.

According to embodiments of the present disclosure, a three-dimensional integrated circuit includes a first CMOS wafer, a second CMOS wafer disposed on and electrically connected to the first CMOS wafer, one or more thick metal layers comprising an inductive device disposed on the second CMOS wafer opposite the first CMOS wafer, and a grounded shield configured to isolate the inductive device from the first CMOS wafer and the second CMOS wafer.

According to embodiments of the present disclosure, a method of making a three-dimensional integrated circuit includes fabricating a first CMOS wafer comprising first circuitry, fabricating a second CMOS wafer comprising second circuitry, electrically connecting the first CMOS wafer and the second CMOS wafer, and electrically connecting one or more metal layers comprising an inductive device to the backside of a second CMOS wafer. The three-dimensional integrated circuit includes a grounded shield positioned between the second circuitry of the second CMOS wafer and the one or more metal layers comprising the inductive device. The grounded shield is configured to electrically and magnetically isolate the inductive device from the second circuitry.

### BRIEF DESCRIPTION OF THE DRAWINGS

Various embodiments of the present disclosure will be understood more fully from the detailed description given below and from the accompanying drawings. In the drawings, like reference numbers may indicate identical or functionally similar elements. Embodiments are described in detail hereinafter with reference to the accompanying figures, in which:

FIG. 1 is a diagrammatic cross-section of a 3DIC according to an embodiment of the present disclosure.

FIG. 2 is a diagrammatic top view of a grounded shield according to an embodiment of the present disclosure.

FIG. 3 is a diagrammatic top view of a grounded shield according to an embodiment of the present disclosure.

FIG. 4 is a diagrammatic top view of a grounded shield according to an embodiment of the present disclosure.

FIG. 5A is a diagrammatic top view of a grounded shield according to an embodiment of the present disclosure.

FIG. 5B is an enlarged partial view of the grounded shield of FIG. 5A.

FIG. 6A is a flow chart depicting a method according to an embodiment of the present disclosure.

FIG. 6B is a flow chart depicting a method according to an embodiment of the present disclosure.

### DETAILED DESCRIPTION

Although the claimed subject matter will be described in terms of certain embodiments and examples, other embodiments and examples, including embodiments and examples that do not provide all of the benefits and features set forth herein, are also within the scope of this disclosure. Various structural, logical, and process step changes may be made without departing from the scope of the disclosure.

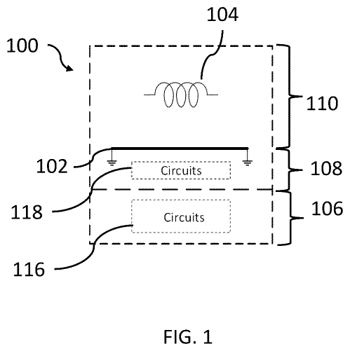

With reference to FIG. 1, a 3DIC 100 includes a first wafer 106 including first circuitry 116, a second wafer 108 including second circuitry 118, and one or more thick metal layers 110 including an inductive device 104. In some embodiments, the first circuity 116 and/or the second circuity 118 may include a switch, a transistor, a resistor, a diode, a varactor, a capacitor, or combinations thereof. The inductive device 104 may include any component capable of storing energy in a magnetic field when an electric current flows through it, e.g., an inductor. The 3DIC 100 further includes a grounded shield 102 positioned between the inductive device 104 and the first and second circuitries 116, 118. The grounded shield 102 is configured to electrically and/or magnetically isolate the inductive device 104 from the first and second circuitries 116, 118. Although two wafers 106, 108 are shown in FIG. 1, the 3DIC 100 may include a single wafer or more than two wafers.

In any embodiment, the grounded shield 102 may be formed of silicon (e.g., a highly doped silicon), polysilicon, or combinations thereof. In some embodiments, the grounded shield 102 includes multiple layers. In such embodiments, the grounded shield 102 may include a first layer formed of polysilicon and a second layer formed of silicon. In some embodiments, the grounded shield 102 is formed of a metal. In some embodiments, the grounded shield 102 includes multiple layers of metal. In some embodiments, the grounded shield 102 includes at least one layer formed of silicon and/or polysilicon and at least one layer formed of metal. In some embodiments, the grounded shield 102 is integrally formed with the second wafer 108. In some embodiments, the grounded shield 102 is formed on a backside of the second wafer 108. In some embodiments, the grounded shield 102 includes a first layer integrally formed with the second wafer 108 and a second layer formed on the backside of the second wafer 108.

In some embodiments, the 3DIC 100 includes one or more thin metal layers formed on a backside of the second wafer 108 and the grounded shield 102 formed between the thin metal layers and the thick metal layers 110. In such embodiments, a second grounded shield 102 may be included between the thin metal layers and the second wafer 108.

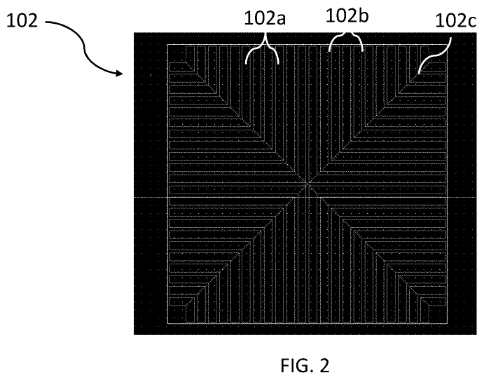

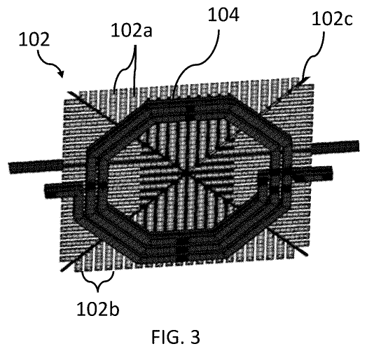

Turning to FIG. 2, the grounded shield 102 is shown in isolation. The grounded shield 102 includes ground strips 102a spaced by gaps 102b. The ground strips 102a are in contact with and grounded by a grounding wire 102c. The grounding wire 102c forms an X-shape through the grounded shield and contacts interior portions of the ground strips 102a. FIG. 3 shows the grounded shield 102 and the inductive device 104. As shown, the grounded shield 102 has a larger area than the inductive device 104 and may therefore shield components, such as circuitry, positioned below the grounded shield 102.

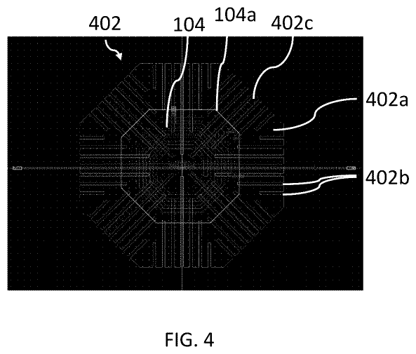

The shape of the grounded shield 102 and the configuration of the ground strips 102a and gaps 102b are not limited to the configuration shown in FIGS. 2 and 3. For example, FIG. 4 shows a grounded shield 402 having an interconnected ground strip 402a. The gaps 402b do not completely isolate the ground strip 402a into discrete sections. The ground strip 402a is in contact with and grounded via the grounding wire 402c. The shape of the grounded shield 402 matches the shape of the inductive device 104 and the inductive area 104a. In any embodiment, the grounded shield 102/402 may be sized and positioned to completely cover the inductive area 104a. In some embodiments, the grounded shield 102/402 has an area that is at least 25%, at least 50%, at 75%, or at least 100% larger than the inductive area 104a.

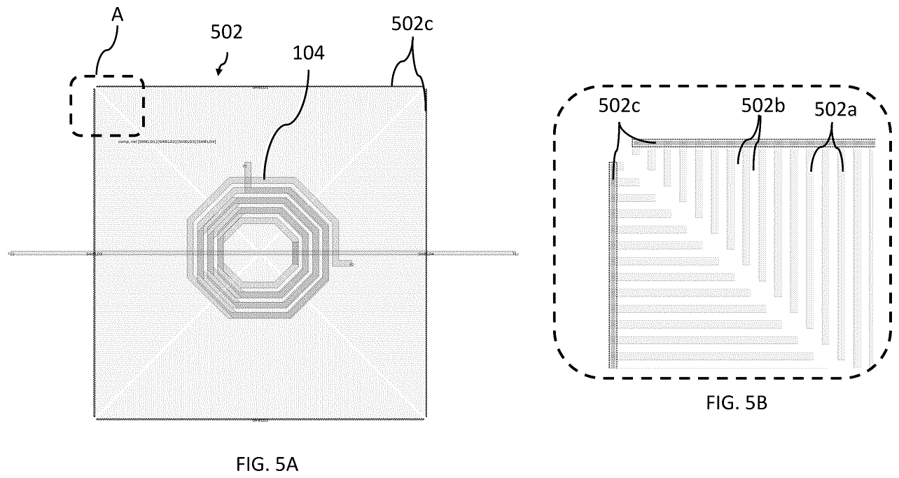

Turning to FIG. 5A and FIG. 5B, a grounded shield 502 and the inductive device 104 are shown. FIG. 5B shows an enlarged view of the grounded shield 502 in area A in FIG. 5A. The grounded shield 502 includes ground strips 502a spaced by gaps 502b. The ground strips 502a are in contact with and grounded via a grounding wire 502c. The grounding wire 502c is positioned around a periphery of the grounded shield 502.

In any embodiment, the 3DIC 100 may include the grounded shield 402 and/or 502 in place of or in addition to the grounded shield 102. In any embodiment, the grounded shield may be patterned, such as in the patterns shown in FIGS. 2-5A. Any combination of the patterns shown and described may be used. Any suitable configuration may be used for the grounding wire, such as the X-shape and/or peripheral configurations described above.

In some embodiments, the 3DIC 100 is radio frequency front end control interface (RFFE) integrated circuit. In some embodiments, the 3DIC 100 is an ultra-high band (UHB) low noise amplifier (LNA). In non-stacked (two-dimensional or 2D) UHB LNAs, one or more inductive devices may utilize 10-11% of the footprint and additional area is required to space the inductive device(s) from other components. Utilizing the grounded shield described herein may allow for a stacked (3D) UHB LNA with a 25% or greater reduction in footprint as compared with non-stacked UHB LNAs. In some embodiments, the 3DIC 100 includes a bias circuit. In comparison to 2D bias circuits, the 3D bias circuit including the grounded shield may have about a 47% reduced footprint. In some embodiments, the 3DIC 100 includes an LC circuit. In 2D LC circuits, the need for high Q factor and high isolation results in a large footprint whereas a 3D LC circuit including the grounded shield may have about a 60% reduction in footprint.

The grounded shield of the present disclosure may enable 3D stacking of traditionally 2D integrated circuits that include an inductive device. The grounded shield may also enable greater flexibility in the design of existing 3DICs as the positioning of inductive devices relative to other components is less restricted when utilizing the grounded shield. Using the grounded shield in the manner described herein may maintain or improve the Q factor and inductance of the inductive device and improve signal isolation.

In any embodiment, the grounded shield may be incorporated into any semiconductor wafer or chip, such as the 3DIC described above. The semiconductor wafers or chips may be incorporated into an electronic device, such as a mobile phone.

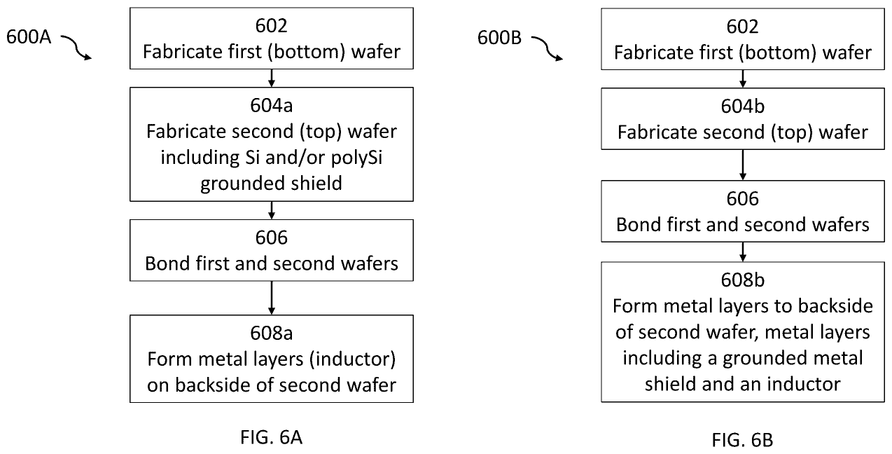

Turning to FIG. 6A, a method 600A is shown. The method 600A includes a step 602 of fabricating a first CMOS wafer (or chip). This may be done using known techniques, such as silicon on insulator (SOI) technology. Step 604a includes fabricating a second CMOS wafer (or chip) including a grounded shield, such as the grounded shield described above. The grounded shield is integrally formed with the second CMOS wafer and may be comprised of a silicon and/or a polysilicon material of the second CMOS wafer. The method 600A further includes a step 606 of bonding and electrically connecting the first CMOS wafer and the second CMOS wafer. The 3DIC may include two or more stacked chips or wafers, wherein at least the topmost includes the grounded shield described herein. In some embodiments, the 3DIC includes only a single chip or wafer. In any embodiment, any one or more of the chips or wafers present in the 3DIC may include circuitry or a combination of circuitries, such as those described above. Step 606 may be achieved using known techniques, such as chip-on-wafer or wafer-on-wafer technologies. The method 600A further includes a step 608a of forming thick metal layers on the backside of the second CMOS wafer (or chip). The thick metal layers include an inductive device. The grounded shield is configured to electrically and/or magnetically isolate the inductive device from components within the first CMOS wafer and/or the second CMOS wafer, such as circuitry. The method 600A may include additional steps, such as incorporating the 3DIC into an electronic device, operating the electronic device, and/or electrically and/or magnetically shielding the inductive device from circuitry within the 3DIC via the grounded shield.

Turning to FIG. 6B, a method 600B is shown. The method 600B includes the step 602 as described above. Step 604b includes fabricating a second CMOS wafer (or chip), which may be achieved in the manner described for step 602 above. The method 600B further includes the step 606 as described above. Next, the method 600B includes a step 608b of forming a grounded shield on the backside of the second CMOS wafer (or chip) and forming thick metal layers on the grounded shield. The thick metal layers include an inductive device. The grounded shield may be formed from a metal and is configured to electrically and/or magnetically isolate the inductive device from components within the first CMOS wafer and/or the second CMOS wafer, such as circuitry. The method 600B may include additional steps, such as incorporating the 3DIC into an electronic device, operating the electronic device, and/or electrically and/or magnetically shielding the inductive device from circuitry within the 3DIC via the grounded shield.

An integrated circuit has been described herein. The integrated circuit includes a first wafer comprising first circuitry, an inductor positioned above the first wafer, and a grounded shield positioned between the inductor and the first circuitry of the first wafer.

The integrated circuit may include any one or more of the following features: wherein the circuitry comprises a switch, a transistor, a capacitor, a resistor, a varactor, a diode, or combinations thereof; wherein the grounded shield is configured to electrically and magnetically isolate the inductor from the first circuitry; a second wafer stacked above the first wafer between the first wafer and the inductor, wherein the grounded shield is positioned at an interface between the inductor and the second wafer; wherein the second wafer comprises second circuitry and the grounded shield is configured to electrically and magnetically isolate the inductor from the first circuitry and the second circuitry; wherein the grounded shield is patterned; wherein the grounded shield comprises silicon, polysilicon, or combinations thereof; and/or wherein the grounded shield comprises a first layer comprising silicon and a second layer comprising polysilicon; wherein the grounded shield comprises a metal.

The integrated circuit may be a radio frequency front end control interface (RFFE) integrated circuit, optionally a low noise amplifier (LNA). The integrate circuit may be incorporated into an electronic device.

A three-dimensional integrated circuit has been described herein. The three-dimension integrated circuit includes a first CMOS wafer, a second CMOS wafer disposed on and electrically connected to the first CMOS wafer, one or more thick metal layers comprising an inductive device disposed on the second CMOS wafer opposite the first CMOS wafer, and a grounded shield configured to isolate the inductive device from the first CMOS wafer and the second CMOS wafer.

The three-dimensional integrated circuit may include any one or more of the following features: wherein the first CMOS wafer comprises a switch, transistor, resistor, diode, varactor, or capacitor electrically and magnetically isolated from the inductive device via the grounded shield; wherein an area of the grounded shield is greater than an area of the switch, transistor, or capacitor of the first CMOS wafer; wherein the second CMOS wafer comprises a switch, transistor, resistor, diode, varactor, or capacitor electrically and magnetically isolated from the inductive device via the grounded shield; and/or wherein the grounded shield comprises silicon, polysilicon, metal, or combinations thereof and is grounded to a conductive structure within the three-dimensional integrated circuit.

The three-dimensional integrated circuit may be a radio frequency front end control interface (RFFE) integrated circuit, optionally a low noise amplifier (LNA). The three-dimensional integrate circuit may be incorporated into an electronic device.

A method of making a three-dimensional integrated circuit has been described herein. The method includes fabricating a first CMOS wafer, fabricating a second CMOS wafer, electrically connecting the first CMOS wafer and the second CMOS wafer, electrically connecting one or more metal layers comprising an inductive device to the backside of a second CMOS wafer. The three-dimensional integrated circuit comprises a grounded shield positioned between the second circuitry of the second CMOS wafer and the one or more metal layers comprising the inductive device, the grounded shield configured to electrically and magnetically isolate the inductive device from the second circuitry.

The method may include any one or more of the following features: wherein fabricating the second CMOS wafer comprises fabricating the grounded shield, wherein the grounded shield comprises silicon, polysilicon, or combinations thereof; and/or further comprising fabricating the grounded shield on a backside of the second CMOS wafer after electrically connecting the first CMOS wafer and the second CMOS wafer, wherein the grounded shield comprises a metal.

Although various embodiments have been shown and described, the disclosure is not limited to such embodiments and will be understood to include all modifications and variations as would be apparent to one of ordinary skill in the art. Therefore, it should be understood that the disclosure is not intended to be limited to the particular forms disclosed; rather, the intention is to cover all modifications, equivalents, and alternatives falling within the spirit and scope of the disclosure as defined by the appended claims.

What is claimed is:

1. An integrated circuit, comprising:
a first wafer comprising first circuitry;
an inductor positioned above the first wafer; and
a grounded shield positioned between the inductor and the first circuitry of the first wafer.

2. The integrated circuit of claim 1, wherein the circuitry comprises a switch, a transistor, a capacitor, a resistor, a varactor, a diode, or combinations thereof; and
wherein the grounded shield is configured to electrically and magnetically isolate the inductor from the first circuitry.

3. The integrated circuit of claim 1, further comprising a second wafer stacked above the first wafer between the first wafer and the inductor, wherein the grounded shield is positioned at an interface between the inductor and the second wafer.

4. The integrated circuit of claim 3, wherein the second wafer comprises second circuitry and the grounded shield is configured to electrically and magnetically isolate the inductor from the first circuitry and the second circuitry.

5. The integrated circuit of claim 1, wherein the grounded shield is patterned.

6. The integrated circuit of claim 5, wherein the grounded shield comprises silicon, polysilicon, or combinations thereof.

7. The integrated circuit of claim 5, wherein the grounded shield comprises a first layer comprising silicon and a second layer comprising polysilicon.

8. The integrated circuit of claim 1, wherein the grounded shield comprises a metal.

9. The integrated circuit of claim 1, which is a radio frequency front end control interface (RFFE) integrated circuit.

10. The integrated circuit of claim 9, which is a low noise amplifier (LNA).

11. An electronic device comprising the integrated circuit of claim 1.

12. A three-dimensional integrated circuit, comprising:
a first CMOS wafer;
a second CMOS wafer disposed on and electrically connected to the first CMOS wafer;
one or more thick metal layers comprising an inductive device disposed on the second CMOS wafer opposite the first CMOS wafer; and
a grounded shield configured to isolate the inductive device from the first CMOS wafer and the second CMOS wafer.

13. The three-dimensional integrated circuit of claim 12, wherein the first CMOS wafer comprises a switch, transistor, resistor, diode, varactor, or capacitor electrically and magnetically isolated from the inductive device via the grounded shield.

14. The three-dimensional integrated circuit of claim 13, wherein an area of the grounded shield is greater than an area of the switch, transistor, or capacitor of the first CMOS wafer.

15. The three-dimensional integrated circuit of claim 12, wherein the second CMOS wafer comprises a switch, transistor, resistor, diode, varactor, or capacitor electrically and magnetically isolated from the inductive device via the grounded shield.

16. The three-dimensional integrated circuit of claim 12, wherein the grounded shield comprises silicon, polysilicon, metal, or combinations thereof and is grounded to a conductive structure within the three-dimensional integrated circuit.

17. The three-dimensional integrated circuit of claim 12, which is a low noise amplifier.

18. A method of making a three-dimensional integrated circuit, comprising:
fabricating a first CMOS wafer comprising first circuitry;
fabricating a second CMOS wafer comprising second circuitry;
electrically connecting the first CMOS wafer and the second CMOS wafer; and
electrically connecting one or more metal layers comprising an inductive device to the backside of a second CMOS wafer; and
wherein the three-dimensional integrated circuit comprises a grounded shield positioned between the second circuitry of the second CMOS wafer and the one or more metal layers comprising the inductive device, the grounded shield configured to electrically and magnetically isolate the inductive device from the second circuitry.

19. The method of claim 18, wherein fabricating the second CMOS wafer comprises fabricating the grounded shield, wherein the grounded shield comprises silicon, polysilicon, or combinations thereof.

20. The method of claim 18, further comprising fabricating the grounded shield on a backside of the second CMOS wafer after electrically connecting the first CMOS wafer and the second CMOS wafer, wherein the grounded shield comprises a metal.
